(19) United States
(12) Patent Application Publication
(10) Pub. No.: US 2024/0258987 A1
(43) Pub. Date: Aug. 1, 2024

(54) ACOUSTIC WAVE DEVICE

(71) Applicant: Murata Manufacturing Co., Ltd., Nagaokakyo-shi (JP)

(72) Inventor: Takashi YAMANE, Nagaokakyo-shi (JP)

(21) Appl. No.: 18/611,883

(22) Filed: Mar. 21, 2024

Related U.S. Application Data
(63) Continuation of application No. PCT/JP2022/036819, filed on Sep. 30, 2022.
(60) Provisional application No. 63/250,641, filed on Sep. 30, 2021.

(51) Int. Cl. H03H 9/05; H03H 9/17

(52) U.S. Cl. CPC H03H 9/0523; H03H 9/173

(57) ABSTRACT

An acoustic wave device includes a mounting substrate; an acoustic wave element on one major surface of the mounting substrate in its thickness direction, and a bump between the acoustic wave element and the mounting substrate. The acoustic wave element includes a support substrate including an air gap, a piezoelectric layer stacked on the support substrate and including an overlap region at least partially overlapping the air gap as viewed in the stacking direction, and a functional electrode located in the overlap region of the piezoelectric layer. The mounting substrate includes a metal portion. A fixed capacitance generated between the acoustic wave element and the mounting substrate is not less than a variable capacitance generated between the acoustic wave element and the mounting substrate.

### CROSS REFERENCE TO RELATED APPLICATIONS

This application claims the benefit of priority to Provisional Application No. 63/250,641, filed on Sep. 30, 2021, and is a Continuation Application of PCT Application No. PCT/JP2022/036819, filed on Sep. 30, 2022. The entire contents of each application are hereby incorporated herein by reference.

### BACKGROUND OF THE INVENTION

### 1. Field of the Invention

The present disclosure relates to acoustic wave devices each including a piezoelectric layer.

### 2. Description of the Related Art

For example, Japanese Unexamined Patent Application Publication No. 2012-257019 discloses an acoustic wave device using plate waves. The acoustic wave device according to Japanese Unexamined Patent Application Publication No. 2012-257019 includes a support, a piezoelectric substrate, and an IDT electrode. The support is provided with an air gap. The piezoelectric substrate is provided on the support so as to overlap the air gap. The IDT electrode is provided on the piezoelectric substrate so as to overlap the air gap. In the acoustic wave device, the IDT electrode excites plate waves. The edge of the air gap does not include any straight portion extending in parallel to the propagation direction of plate waves excited by the IDT electrode.

In recent years, there has been demand for an acoustic wave device with minimized variations in characteristics.

### SUMMARY OF THE INVENTION

Example embodiments of the present invention provide acoustic wave devices each with minimized variations in characteristics.

An acoustic wave device according to an example embodiment of the present invention includes a mounting substrate, an acoustic wave element positioned on one major surface of the mounting substrate in a thickness direction of the mounting substrate, and a bump between the acoustic wave element and the mounting substrate. The acoustic wave element includes a support substrate including an air gap, a piezoelectric layer stacked on the support substrate and including an overlap region at least partially overlapping the air gap as viewed in a stacking direction of the piezoelectric layer, and a functional electrode located in the overlap region of the piezoelectric layer. The mounting substrate includes a metal portion, and a fixed capacitance generated between the acoustic wave element and the mounting substrate is not less than a variable capacitance generated between the acoustic wave element and the mounting substrate.

According to example embodiments of the present invention, it is possible to provide acoustic wave devices each with minimized variations in characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a schematic perspective view illustrating an appearance of an acoustic wave element of example embodiments of the present invention.

FIG. 1B is a plan view illustrating an electrode structure on a piezoelectric layer of an example embodiment of the present invention.

FIG. 2 is a cross-sectional view along line A-A in FIG. 1A.

FIG. 3A is a schematic elevational cross-sectional view explaining Lamb waves propagating in a piezoelectric film of an acoustic wave element in the related art.

FIG. 3B is a schematic elevational cross-sectional view explaining waves in an acoustic wave element according to an example embodiment of the present invention.

FIG. 4 is a schematic diagram illustrating bulk waves when voltage is applied across a first electrode and a second electrode such that the potential of the second electrode is higher than that of the first electrode.

FIG. 5 is a diagram illustrating resonance characteristics of an acoustic wave element according to a first example embodiment of the present invention.

FIG. 6 is a diagram illustrating the relationship between d/2p and fractional bandwidth of an acoustic wave element as a resonator.

FIG. 7 is a plan view of another acoustic wave element according to the first example embodiment of the present invention.

FIG. 8 is a reference diagram illustrating an example of resonance characteristics of an acoustic wave element.

FIG. 9 is a diagram illustrating the relationship between the fractional bandwidth and the amount of phase rotation of spurious impedance, which is normalized by 180 degrees, as the magnitude of spurious components, when many acoustic wave resonators are provided.

FIG. 10 is a diagram illustrating the relationship between d/2p, a metallization ratio MR, and a fractional bandwidth.

FIG. 11 is a diagram illustrating a fractional bandwidth map with respect to Euler angles (0°, θ, ψ) of LiNbO₃ when d/p is reduced infinitesimally close to zero.

FIG. 12 is a partially-cutaway perspective view for explaining an acoustic wave element according to the first example embodiment of the present invention.

FIG. 13 is a schematic elevational cross-sectional view illustrating an acoustic wave device of a second example embodiment of the present invention.

FIG. 14 is a plan view of the acoustic wave device of FIG. 13.

FIG. 15 is a diagram illustrating the change rate of capacitance per unit height of a bump dimension.

FIG. 16 is a diagram illustrating the relationship between the bump dimension and variable capacitance.

FIG. 17 is a diagram illustrating the relationship between resonant frequency and a fractional bandwidth ratio to that without a mounting substrate.

FIG. 18 is results from FIGS. 15 to 17.

FIG. 19 is a schematic elevational cross-sectional view illustrating a first modification of the acoustic wave device of FIG. 13.

FIG. 20 is a schematic elevational cross-sectional view illustrating a second modification of the acoustic wave device of FIG. 13.

FIG. 21 is a schematic elevational cross-sectional view illustrating a third modification of the acoustic wave device of FIG. 13.

### DETAILED DESCRIPTION OF THE EXAMPLE EMBODIMENTS

Acoustic wave elements of example embodiments of the present invention include, for example, a piezoelectric layer made of lithium niobate or lithium tantalate, and a first electrode and a second electrode opposing each other in a direction transverse to the thickness direction of the piezoelectric layer.

An acoustic wave element according to an example embodiment uses first thickness-shear mode bulk waves.

In an acoustic wave element according to an example embodiment, the first electrode and the second electrode are electrodes adjacent to each other, and d/p is not greater than, for example, about 0.5 where d is the thickness of the piezoelectric layer and p is the center-to-center distance between the first and second electrodes. According to the above-described example embodiments, therefore, the acoustic wave elements can increase in Q factor even when reduced in size.

An acoustic wave element according to an example embodiment uses Lamb waves as plate waves and can provide resonance characteristics by Lamb waves.

An acoustic wave element according to an example embodiment of the present invention includes, for example, a piezoelectric layer made of lithium niobate or lithium tantalate, and an upper electrode and a lower electrode that oppose each other in the thickness direction of the piezoelectric layer with the piezoelectric layer interposed therebetween. The acoustic wave element of the fourth example embodiment uses bulk waves.

Hereinafter, the present invention is clarified by describing example embodiments of acoustic wave elements with reference to the drawings.

The example embodiments described in the specification are illustrative. Some components of each example embodiment can be substituted or combined with components of another example embodiment.

### First Example Embodiment

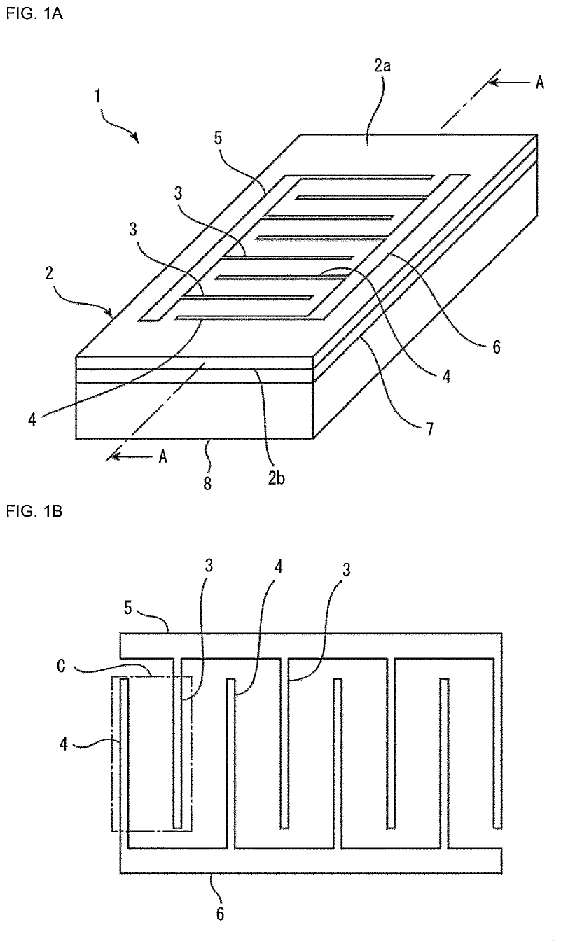

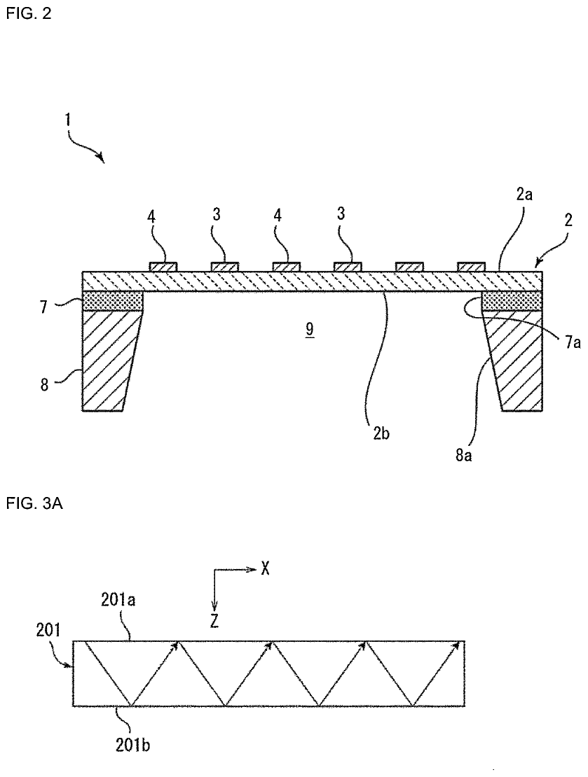

FIG. 1A is a schematic perspective view illustrating an appearance of an acoustic wave element according to a first example embodiment of the present invention in relation to first and second aspects. FIG. 1B is a plan view illustrating an electrode structure on the piezoelectric layer. FIG. 2 is a cross-sectional view of a portion along line A-A in FIG. 1A.

An acoustic wave element 1 includes a piezoelectric layer 2 made of, for example, LiNbO₃. The piezoelectric layer 2 may be made of, for example, LiTaO₃. In the present example embodiment, the cut angle of LiNbO₃ or LiTaO₃ is set to Z-cut. However, rotated Y-cut or X-cut may be used. Preferably, a propagation orientation is, for example, Y-propagation and X-propagation about ±30°. The thickness of the piezoelectric layer 2 is not limited in particular but is preferably, for example, not less than about 50 nm and not greater than about 1000 nm for effective excitation of the first thickness-shear mode.

The piezoelectric layer 2 includes a first major surface 2a and a second major surface 2b, which oppose each other. On the first major surface 2a, electrodes 3 and electrodes 4 are provided. Herein, the electrodes 3 are an example of the “first electrode”, and the electrodes 4 are an example of the “second electrode”. In FIGS. 1A and 1B, the plural electrodes 3 are plural first electrode fingers coupled to a first busbar 5. The plural electrodes 4 are plural second electrode fingers coupled to a second busbar 6. The plural electrodes 3 are interdigitated with the plural electrodes 4.

The electrodes 3 and 4 each have a rectangular or substantially rectangular shape and with a length direction. Each electrode 3 opposes the electrodes 4 adjacent thereto in a direction perpendicular or substantially perpendicular to the length direction. These plural electrodes 3 and 4, first busbar 5, and second busbar 6 define an interdigital transducer (IDT) electrode. Both the length direction of the electrodes 3 and 4 and the direction perpendicular or substantially perpendicular to the length direction of the electrodes 3 and 4 are transverse to the thickness direction of the piezoelectric layer 2. That is, each electrode 3 opposes the electrodes 4 adjacent thereto in a direction transverse to the thickness direction of the piezoelectric layer 2.

The length direction of the electrodes 3 and 4 may be replaced with a direction perpendicular or substantially perpendicular to the length direction of the electrodes 3 and 4 illustrated in FIGS. 1A and 1B. Specifically, the electrodes 3 and 4 may extend in the direction where the first busbar 5 and the second busbar 6 extend in FIGS. 1A and 1B. In this case, the first busbar 5 and the second busbar 6 extend in the direction where the electrodes 3 and 4 extend in FIGS. 1A and 1B.

Plural structure pairs each including adjacent electrodes 3 and 4 that are respectively coupled to one potential and the other potential are provided in the direction perpendicular or substantially perpendicular to the length direction of the electrodes 3 and 4. Herein, the adjacent electrodes 3 and 4 refer to electrodes 3 and 4 that are provided with a space interposed therebetween but not refer to electrodes 3 and 4 that are provided in direct contact with each other.

When the electrodes 3 and 4 are adjacent to each other, any electrode that is coupled to a hot or ground electrode, including the other electrodes 3 and 4, is not between the electrodes 3 and 4. The number of pairs of electrodes 3 and 4 is not necessarily a whole number and may be, for example, 1.5, 2.5, or the like. The center-to-center distance between electrodes 3 and 4, that is, the pitch of the same is preferably, for example, not less than about 1 μm and not greater than about 10 μm. The center-to-center distance between electrodes 3 and 4 refers to the distance between the center of the width dimension of the electrode 3 in the direction perpendicular or substantially perpendicular to the length direction of the electrode 3 and the center of the width dimension of the electrode 4 in the direction perpendicular or substantially perpendicular to the length direction of the electrode 4. Furthermore, either the electrode 3 or the electrode 4, or both, include plural electrodes (when the number of electrode pairs is 1.5 or more, each electrode pair including electrodes 3 and 4), the center-to-center distance between electrodes 3 and 4 refers to the average of the center-to-center distances between adjacent electrodes 3 and 4 of the 1.5 or more pairs of electrodes 3 and 4. The width of electrodes 3 and 4, that is, the dimension of the electrodes 3 and 4 in the direction where the electrodes 3 and 4 oppose each other is preferably, for example, not less than about 150 nm and not greater than about 1000 nm.

In the first example embodiment, since the piezoelectric layer is Z-cut, the direction perpendicular or substantially perpendicular to the length direction of the electrodes 3 and 4 is the direction perpendicular or substantially perpendicular to the polarization direction of the piezoelectric layer 2, except when the piezoelectric layer 2 includes a piezoelectric substance with another cut angle. Herein, “being perpendicular” is not limited to only “being exactly perpendicular” and may include “being substantially perpendicular (the angle between the direction perpendicular to the length direction of the electrodes 3 and 4 and the polarization direction may be, for example, about 90°±10°)”.

On the second major surface 2b side of the piezoelectric layer 2, a support 8 is laid with an insulating layer 7 interposed therebetween. The insulating layer 7 and the support 8 are frame-shaped and include cavities 7a and 8a as illustrated in FIG. 2. The cavities 7a and 8a define an air gap 9. The air gap 9 is provided not to impede vibration in an excitation region C of the piezoelectric layer 2. The support 8 is provided on the second major surface 2b with the insulating layer 7 interposed therebetween in such a position as not to overlap a portion where at least one pair of electrodes 3 and 4 is provided. The insulating layer 7 is not necessarily provided. The support 8 can therefore be laid directly or indirectly on the second major surface 2b of the piezoelectric layer 2.

The insulating layer 7 is made of, for example, silicon oxide. In addition to silicon oxide, the insulating layer 7 can be made of a proper insulating material, such as, for example, silicon oxynitride or alumina. The support 8 is made of, for example, Si. The plane orientation of Si in the surface close to the piezoelectric layer 2 may be (100), (110), or (111). Preferably, the support 8 is made of high-resistance Si with a resistivity of, for example, not less than about 4 kΩ. The support 8 can be made of a proper insulating material or a proper semiconductor material. Examples of the material of the support 8 can include piezoelectric substances, such as aluminum oxide, lithium tantalate, lithium niobate, and quartz crystal, various ceramics, such as alumina, magnesia, sapphire, silicon nitride, aluminum nitride, silicon carbide, zirconia, cordierite, mullite, steatite, and forsterite, dielectrics, such as diamond and glass, and semiconductors, such as gallium nitride.

The above-described plural electrodes 3 and 4, first busbar 5, and second busbar 6 are made of a proper metal or alloy, such as, for example, Al or AlCu alloy. In the first example embodiment, the plural electrodes 3 and 4, first busbar 5, and second busbar 6 each include an Al film provided on a Ti film. The plural electrodes 3 and 4, first busbar 5, and second busbar 6 may include an adhesion layer other than Ti film.

To drive the acoustic wave element 1, alternating-current voltage is applied across the plural electrodes 3 and the plural electrodes 4. To be more specific, alternating-current voltage is applied across the first busbar 5 and the second busbar 6. This can provide resonance characteristics using first thickness-shear mode bulk waves excited in the piezoelectric layer 2.

In the acoustic wave element 1, furthermore, d/p is, for example, not greater than about 0.5 where d is the thickness of the piezoelectric layer 2 and p is the center-to-center distance between any adjacent electrodes 3 and 4 of the plural pairs of electrodes 3 and 4. The first thickness-shear mode bulk waves can therefore be excited effectively, thus providing good resonance characteristics. More preferably, for example, d/p is not greater than about 0.24. This can provide much better resonance characteristics.

When either the electrode 3 or the electrode 4, or both, include plural electrodes like the first example embodiment, that is, when the acoustic wave element 1 includes 1.5 or more electrode pairs, where an electrode 3 and an electrode 4 constitute a pair, the center-to-center distance p between adjacent electrodes 3 and 4 refers to the average of the center-to-center distances between the adjacent electrodes 3 and 4.

In the acoustic wave element 1 of the first example embodiment, due to the aforementioned configuration, the Q factor is less likely to decrease even when the number of pairs of electrodes 3 and 4 is reduced for size reduction. This is because the aforementioned configuration constitutes a resonator not requiring reflectors on both sides and produces a very small propagation loss. The reflectors are not required because the acoustic wave element 1 uses first thickness-shear mode bulk waves.

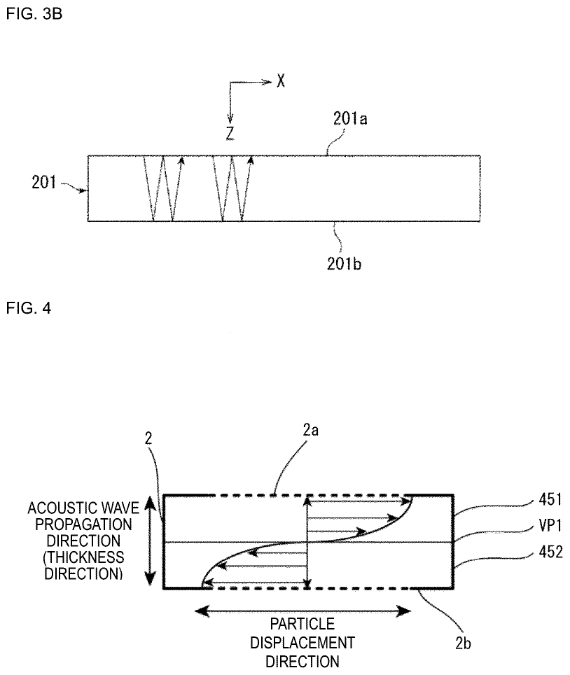

The difference between Lamb waves used in an acoustic wave element in the related art and the aforementioned first thickness-shear mode bulk waves will be described with reference to FIGS. 3A and 3B.

FIG. 3A is a schematic elevational cross-sectional view for explaining Lamb waves propagating in the piezoelectric film of an acoustic wave element in the related art. The acoustic wave element in the related art is described in Japanese Unexamined Patent Application Publication No. 2012-257019, for example. As illustrated in FIG. 3A, in the acoustic wave element in the related art, waves propagate in a piezoelectric film 201 as indicated by arrows. Herein, in the piezoelectric film 201, a first major surface 201a and a second major surface 201b oppose each other, and the thickness direction that couples the first major surface 201a to the second major surface 201b is Z direction. X direction is the direction where the electrode fingers of the IDT electrode are arranged. As illustrated in FIG. 3A, Lamb waves propagate in the X direction. Since Lamb waves are plate waves, the entire piezoelectric film 201 vibrates, but the waves propagate in the X direction. The resonance characteristics are obtained by providing reflectors on both sides. This produces a wave propagation loss. When the acoustic wave element is reduced in size, that is, when the number of pairs of electrode fingers is reduced, therefore, the Q factor decreases.

As illustrated in FIG. 3B, in the acoustic wave element 1 of the first example embodiment, the displacement of vibration is in the thickness-shear direction, and most waves propagate in the direction that couples the first major surface 2a of the piezoelectric layer 2 to the second major surface 2b, that is, in the Z direction to resonate. This means that the wave component in the X direction is significantly smaller than the wave component in the Z direction. This wave propagation in the Z direction provides resonance characteristics, thus eliminating the need for reflectors. The propagation loss due to propagation to reflectors is therefore not produced. The Q factor is therefore less likely to decrease even when the number of electrode pairs each including electrodes 3 and 4 is reduced for size reduction.

As illustrated in FIG. 4, the amplitude direction of first thickness-shear mode bulk waves in a first region 451 included in the excitation region C of the piezoelectric layer 2 is opposite to that in a second region 452 included in the excitation region C of the piezoelectric layer 2. FIG. 4 schematically illustrates bulk waves when voltage is applied across the electrodes 3 and the electrodes 4 such that the potential of the electrodes 4 is higher than that of the electrodes 3. The first region 451 is a region between a virtual plane VP1 and the first major surface 2a in the excitation region C. The virtual plane VP1 is perpendicular to the thickness direction of the piezoelectric layer 2 and divides the piezoelectric layer 2 into two. The second region 452 is a region between the virtual plane VP1 and the second major surface 2b in the excitation region C.

As described above, in the acoustic wave element 1, at least one electrode pair including electrodes 3 and 4 is provided, but waves do not propagate in the X direction. The number of electrode pairs each including electrodes 3 and 4 therefore does not need to be greater than 1. That is, the acoustic wave element 1 only needs to include at least one pair of electrodes.

For example, the electrodes 3 are coupled to the hot potential while the electrodes 4 are coupled to the ground potential. However, the electrodes 3 may be coupled to the ground potential while the electrodes 4 are coupled to the hot potential. In the first example embodiment, at least one electrode pair includes an electrode coupled to the hot potential and an electrode coupled to the ground potential as described above, and no floating electrode is provided.

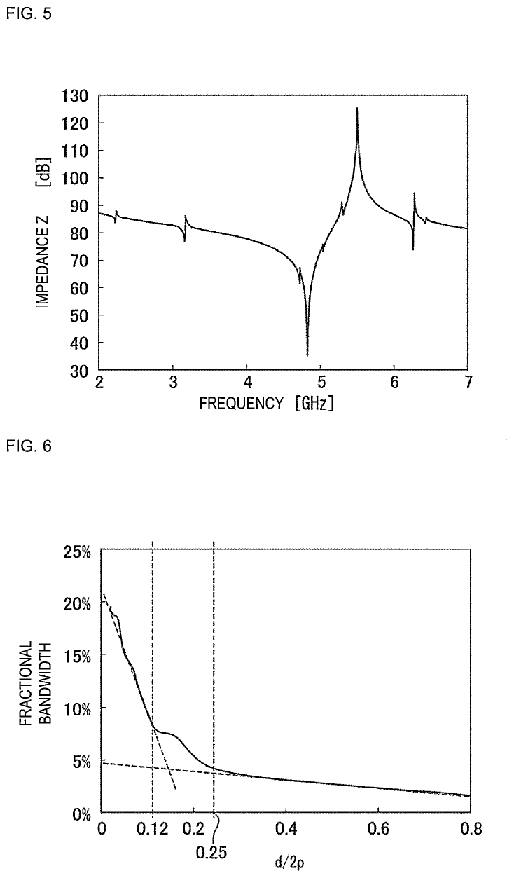

FIG. 5 is a diagram illustrating the resonance characteristics of the acoustic wave element of the first example embodiment of the present invention. The design parameters of the acoustic wave element 1 having these resonance characteristics are as follows.
Piezoelectric layer 2: LiNbO₃ with Euler angles (0°, 0°, 90°), the thickness=about 400 nm

The length of the region where the electrodes 3 and 4 overlap each other as seen in the direction perpendicular to the length direction of the electrodes 3 and 4, that is, the length of the excitation region C=about 40 μm, the number of electrode pairs including the electrodes 3 and 4=21, the center-to-center distance between electrodes=about 3 μm, the width of the electrodes 3 and 4=about 500 nm, and d/p=about 0.133
Insulating layer 7: about 1 μm-thick silicon oxide film
Support 8: Si

The length of the excitation region C is the dimension of the excitation region C in the length direction of the electrodes 3 and 4.

In the first example embodiment, the electrode-to-electrode distance in all of the electrode pairs each including electrodes 3 and 4 is equal or substantially equal. That is, the electrodes 3 and the electrodes 4 are disposed at equal or substantially equal pitch.

As can be seen in FIG. 5, the acoustic wave element 1 has good resonance characteristics with a fractional bandwidth of about 12.5% in spite of not including reflectors.

As described above, d/p is not greater than about 0.5 and more preferably not greater than about 0.24 in the first example embodiment where d is the thickness of the piezoelectric layer 2 and p is the center-to-center distance between electrodes 3 and 4. This will be described with reference to FIG. 6.

By varying d/2p, multiple acoustic wave elements were created in a similar manner to the acoustic wave element having the resonance characteristics illustrated in FIG. 5. FIG. 6 is a diagram illustrating the relationship between this d/2p and the fractional bandwidth of each acoustic wave element as a resonator.

As can be seen in FIG. 6, when d/2p is greater than about 0.25, that is, when d/p>about 0.5, the fractional bandwidth is less than about 5% even if d/p is adjusted. When d/2p≤about 0.25 on the other hand, that is, when d/p≤about 0.5, the fractional bandwidth can be about 5% or higher by changing d/p within that range, and it is possible to create a resonator having a high coupling coefficient. When d/2p is not greater than about 0.12, that is, when d/p is not greater than about 0.24, the fractional bandwidth can be increased to about 7% or higher. In addition, when d/p is adjusted within this range, it is possible to create a resonator with a wider fractional bandwidth, that is, it is possible to implement a resonator having a higher coupling coefficient. This reveals that when d/p is set not greater than about 0.5 like, it is possible to provide a resonator that uses first thickness-shear mode bulk waves and has a high coupling coefficient.

As described above, the at least one electrode pair may include only one electrode pair, and when the at least one electrode pair includes one electrode pair, p described above is the center-to-center distance between the adjacent electrodes 3 and 4. When the at least one electrode pair includes 1.5 or more electrode pairs, p is the average of the center-to-center distances between adjacent electrodes 3 and 4.

When the piezoelectric layer 2 varies in thickness, the thickness d of the piezoelectric layer can be calculated as an average of the thickness of the piezoelectric layer 2.

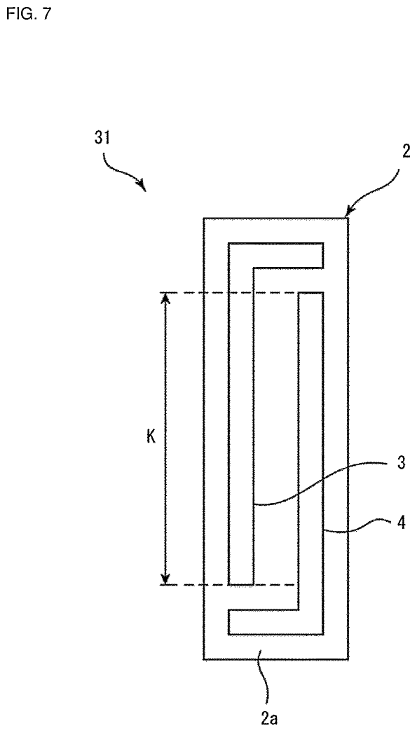

FIG. 7 is a plan view of another acoustic wave element according to the first example embodiment of the present invention. In an acoustic wave element 31, an electrode pair including an electrode 3 and an electrode 4 is provided on the first major surface 2a of the piezoelectric layer 2. K in FIG. 7 indicates an overlap width. As described above, in the acoustic wave element 31 of the present example embodiment, the number of electrode pairs may be one. Even in this case, first thickness-shear mode bulk waves can be effectively excited when d/p described above is not greater than about 0.5.

In the acoustic wave element 1, preferably, for example, a metallization ratio MR satisfies: MR≤about 1.75(d/p)+0.075 where the metallization ratio MR is a metallization ratio of any adjacent electrodes 3 and 4 of the plural electrodes 3 and 4 to the excitation region, which is the region where the adjacent electrodes 3 and 4 overlap each other as seen in the direction where the electrodes 3 and 4 oppose each other. In other words, a metallization ratio MR preferably satisfies: MR≤about 1.75(d/p)+0.075 where the metallization ratio MR is a metallization ratio of plural first electrode fingers and plural second electrode fingers to an excitation region (an overlap region), which is the region where the adjacent plural first and second electrode fingers overlap each other as seen in the direction where the adjacent plural first and second electrode fingers oppose each other. In this case, spurious components can be effectively reduced.

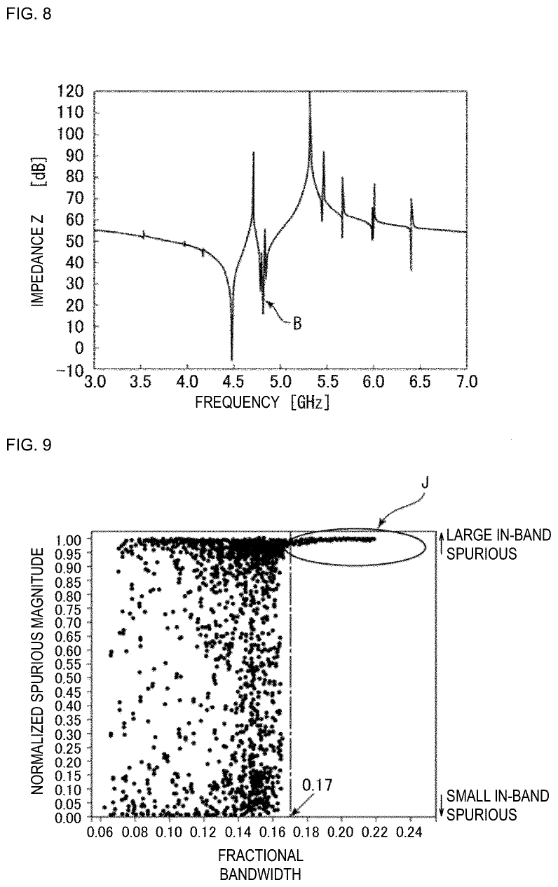

This will be described with reference to FIGS. 8 and 9. FIG. 8 is a reference diagram illustrating an example of resonance characteristics of the aforementioned acoustic wave element 1. Spurious components indicated by an arrow B appear between the resonant frequency and the anti-resonant frequency. Herein, d/p was set to about 0.08, and Euler angles of LiNbO₃ was set to (0°, 0°, 90°). The above-described metallization ratio MR was set to about 0.35.

The metallization ratio MR will be described with reference to FIG. 1B. Focusing on a pair of electrodes 3 and 4 in the electrode structure of FIG. 1B, it is assumed that only this pair of electrodes 3 and 4 is provided. In this case, the portion surrounded by the dashed-dotted line C is the excitation region. This excitation region includes a region of the electrode 3 overlapping the electrode 4 as the electrodes 3 and 4 are seen in the direction perpendicular or substantially perpendicular to the length direction of the electrodes 3 and 4, that is, in the direction where the electrodes 3 and 4 oppose each other, a region of the electrode 4 overlapping the electrode 3, and a region where the electrodes 3 and 4 overlap each other in the region between the electrode 3 and the electrode 4. The metallization ratio MR is the area of the electrodes 3 and 4 in the excitation region C with respect to the area of the excitation region C. That is, the metallization ratio MR is the ratio of the area of the metallized portion to the area of the excitation region.

When the electrode structure includes plural pairs of electrodes, MR can be a ratio of metallized portion included in all the excitation regions to the total area of the excitation regions.

FIG. 9 is a diagram illustrating the relationship between the fractional bandwidth and the amount of phase rotation of spurious impedance, which is normalized by about 180 degrees, as the magnitude of spurious components, when many acoustic wave resonators are provided according to the first example embodiment. The fractional bandwidth was adjusted by variously changing the thickness of the piezoelectric layer and the dimensions of the electrodes. FIG. 9 is the result when the piezoelectric layer was made of Z-cut LiNbO₃. Piezoelectric layers with another cut angle have the same or substantially the same tendency.

In the region surrounded by an ellipse J in FIG. 9, the magnitude of spurious components is as large as about 1.0. As can be seen in FIG. 9, when the fractional bandwidth is greater than about 0.17, that is, greater than about 17%, large spurious components with a spurious level of not less than 1 appear in the pass band even if the parameters defining the fractional bandwidth are changed. Like the resonance characteristics illustrated in FIG. 8, large spurious components indicated by the arrow B appear in the band. It is therefore preferable that the fractional bandwidth is, for example, not greater than about 17%. In this case, spurious components can be reduced by adjusting the film thickness of the piezoelectric layer 2, dimensions of the electrodes 3 and 4, and the like.

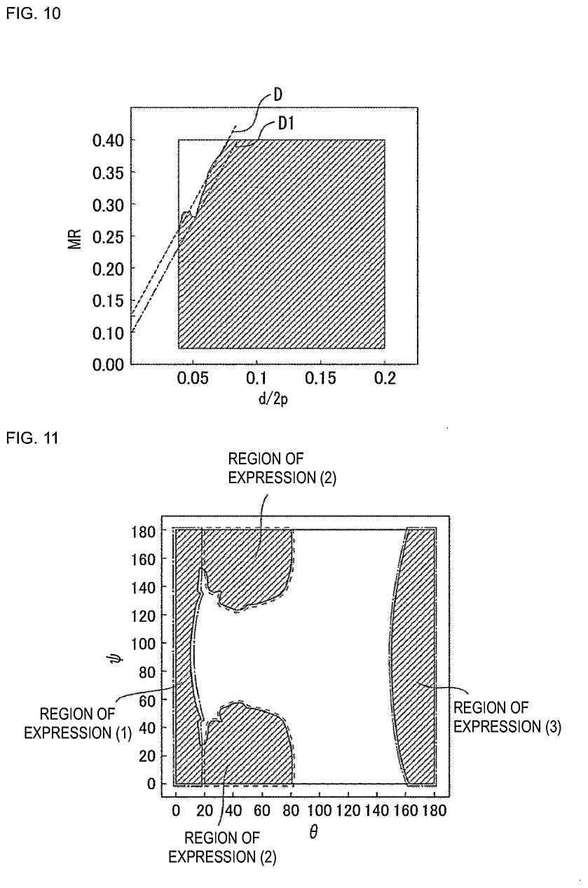

FIG. 10 is a diagram illustrating the relationship between d/2p, the metallization ratio MR, and the fractional bandwidth. Various acoustic wave elements having different values of d/2p and MR were formed according to the aforementioned acoustic wave element, and the fractional bandwidth thereof was measured. The hatched portion to the right of a dashed line D in FIG. 10 is a region in which the fractional bandwidth is not greater than about 17%. The boundary between the region with hatching and the region without hatching is represented by MR=about 3.5(d/2p)+0.075, that is, MR=about 1.75(d/p)+0.075. It is therefore preferable that MR≤about 1.75(d/p)+0.075. In this case, the fractional bandwidth can easily be not greater than about 17%. The region to the right of MR=3.5(d/2p)+0.05 indicated by a dotted-dashed line D1 in FIG. 10 is more preferable. That is, when MR≤about 1.75(d/p)+0.05, the fractional bandwidth can be equal to or less than about 17% reliably.

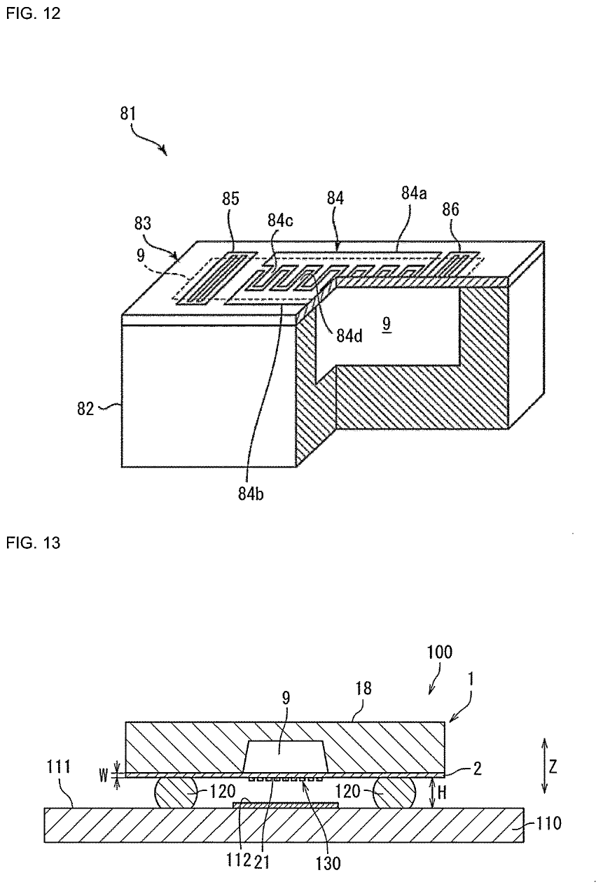

FIG. 11 is a diagram illustrating a fractional bandwidth map with respect to Euler angles (0°, θ, ψ) of LiNbO₃ when d/p is reduced infinitesimally close to zero. Hatched portions in FIG. 11 are regions where the fractional bandwidth is at least not less than about 5%. The ranges of the regions are approximated to the ranges expressed by Expressions (1), (2), and (3) below.

(0°±10°,0° to 20°,any ψ) Expression (1)

(0°±10°,20° to 80°,0° to 60°(1−(θ−50)²/900)^{1/2}) or (0°±10°,20° to 80°,[180°−60°(1−(θ−50)²/900)^{1/2}] to 180°) Expression (2)

(0°±10°,[180°−30°(1−(ψ−90)²/8100)^{1/2}] to 180°, any ψ) Expression (3)

It is therefore preferable that the Euler angles are within the range expressed by Expression (1), (2), or (3) so that the fractional bandwidth can be widened sufficiently.

FIG. 12 is a partially-cutaway perspective view for explaining an acoustic wave element according to the first example embodiment of the present invention. An acoustic wave element 81 includes a support substrate 82. The support substrate 82 is provided with a recess opened in the top surface. On the support substrate 82, a piezoelectric layer 83 is laid. The air gap 9 is thereby formed. An IDT electrode 84 is provided on the piezoelectric layer 83 above the air gap 9. On both sides of the IDT electrode 84 in the acoustic wave propagation direction, reflectors 85 and 86 are provided. In FIG. 12, a dashed line indicates the outer edge of the air gap 9. The IDT electrode 84 includes a first busbar 84a, a second busbar 84b, plural electrodes 84c as first electrode fingers, and plural electrodes 84d as second electrode fingers. The plural electrodes 84c are coupled to the first busbar 84a. The plural electrodes 84d are coupled to the second busbar 84b. The plural electrodes 84c are interdigitated with the plural electrodes 84d.

In the acoustic wave element 81, applying an alternating-current electric field to the IDT electrode 84 above the air gap 9 excites Lamb waves as plate waves. Since the reflectors 85 and 86 are provided on the both sides, the acoustic wave element 81 is able to have resonance characteristics by the Lamb waves.

In such a manner, the acoustic wave element of example embodiments of the present invention may use plate waves.

### Second Example Embodiment

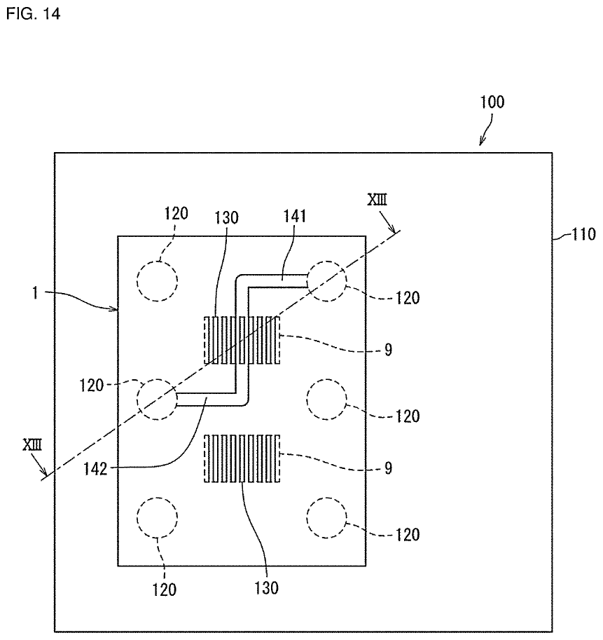

An acoustic wave device 100 of a second example embodiment of the present invention will be described with reference to FIGS. 13 and 14. In the second example embodiment, the description of the contents overlapping the first example embodiment will be properly omitted. The contents described in the first example embodiment can be applied to the second example embodiment.

As illustrated in FIG. 13, the acoustic wave device 100 preferably includes a mounting substrate 110, an acoustic wave element 1, and bumps 120. The acoustic wave element 1 is positioned on one major surface 111 of the mounting substrate 110 in its thickness direction (in the Z direction, for example). The bumps 120 are arranged between the acoustic wave element 1 and the mounting substrate 110.

The acoustic wave element 1 includes a support substrate 18, which includes an air gap 9, a piezoelectric layer 2, which is stacked on the support substrate 18, and a functional electrode 130. The piezoelectric layer 2 is preferably made of, for example, lithium niobate (LN) and includes an overlap region 21 at least partially overlapping the air gap 9 as viewed in the stacking direction (in the Z direction, for example). The support substrate 18 includes, for example, a support 8 and a bonding layer 7, which is provided on the support 8. The functional electrode 130 is, for example, an IDT electrode and is positioned in the overlap region 21 of the piezoelectric layer 2.

The mounting substrate 110 includes a metal portion 112. In the second example embodiment, the metal portion 112 is provided on the one major surface 111 of the mounting substrate 110 and opposes the functional electrode 130 in the thickness direction of the mounting substrate 110.

The acoustic wave device 100 is configured such that a fixed capacitance generated between the acoustic wave element 1 and the mounting substrate 110 is not less than a variable capacitance generated between the acoustic wave element 1 and the mounting substrate 110. This can be provided by, for example, satisfying Expression (1): H×W≥about 4442.9 μm·nm. In Expression (1), H is a bump dimension as a dimension of the bumps 120 in the stacking direction, and W is a piezoelectric layer dimension as a dimension of the piezoelectric layer 2 in the stacking direction (in other words, the thickness of the piezoelectric layer 2).

Capacitance is generated mainly in wiring. For example, in an acoustic wave device 100 illustrated in FIG. 14, capacitance is generated in a route of wiring 141, the mounting substrate 110, and wiring 142. The fixed capacitance is a capacitance not depending on changes in the bump dimension H. The variable capacitance is a capacitance depending on changes in the bump dimension H. For example, the variable capacitance is a capacitance when the bump 120 is increased by about 1 μm.

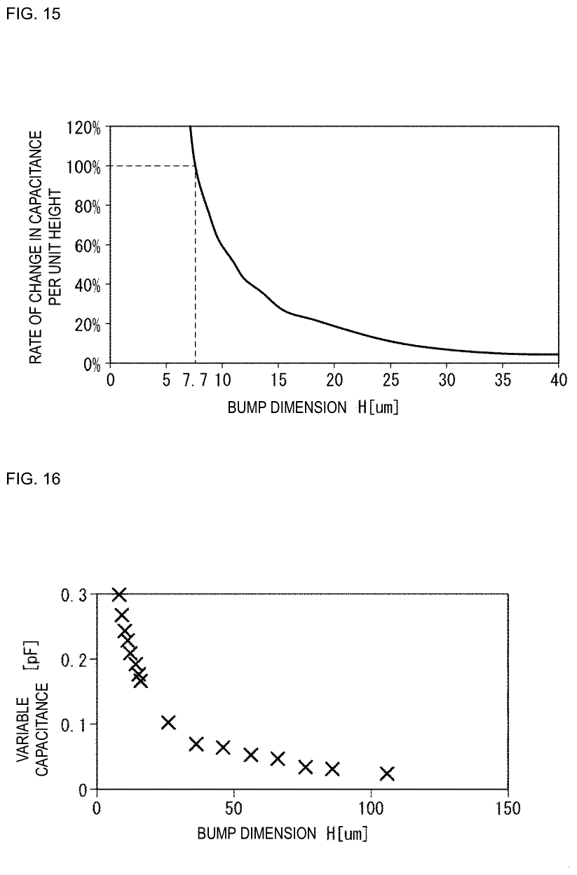

FIG. 15 illustrates the change rate (=variable capacitance/fixed capacitance) in capacitance per unit height (1 μm, for example) of the bump dimension H when the acoustic wave element 1 of the acoustic wave device 100 has a resonant frequency Fr of about 3.2 GHz. As illustrated in FIG. 15, in the acoustic wave device 100 including the acoustic wave element 1 with a resonant frequency Fr about 3.2 GHz, the fixed capacitance is dominant where the bump dimension H≥about 7.7 μm.

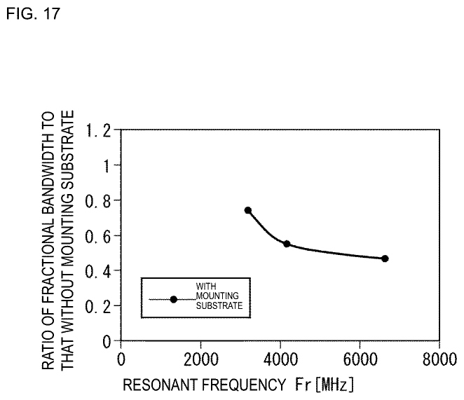

FIG. 16 illustrates the relationship between the bump dimension H and the variable capacitance when d=about 577 nm and Fr=about 3203 MHz. FIG. 17 illustrates the relationship between the resonant frequency Fr and the fractional bandwidth ratio of the acoustic wave element 1 to that without the mounting substrate when H=about 8 μm. “Without the mounting substrate” refers to a situation where the acoustic wave device 100 does not include the mounting substrate 110 (in other words, in the absence of the mounting substrate 110). FIG. 16 reveals that the variable capacitance×the bump dimension H=constant. FIG. 17 reveals that the fractional bandwidth ratio×the resonant frequency=constant. The resonant frequency Fr is inversely proportional to the piezoelectric layer dimension W, and the fractional bandwidth ratio is substantially proportional to the variable capacitance. This means that the following relational expressions are true where a, b, c, and d are constants: the variable capacitance×the bump dimension H=a; the fractional bandwidth ratio×the resonant frequency=b; the resonant frequency×the piezoelectric layer dimension W=c; and the fractional bandwidth ratio=d×the variable capacitance. Using the above relational expressions, the fractional bandwidth ratio×the bump dimension H is expressed by a×d; the fractional bandwidth ratio÷the piezoelectric layer dimension W is expressed by b÷c; and the bump dimension H×the piezoelectric layer dimension W is expressed by a÷b×c×d. Since a, b, c, and d are constants, the bump dimension H×the piezoelectric layer dimension W=constant.

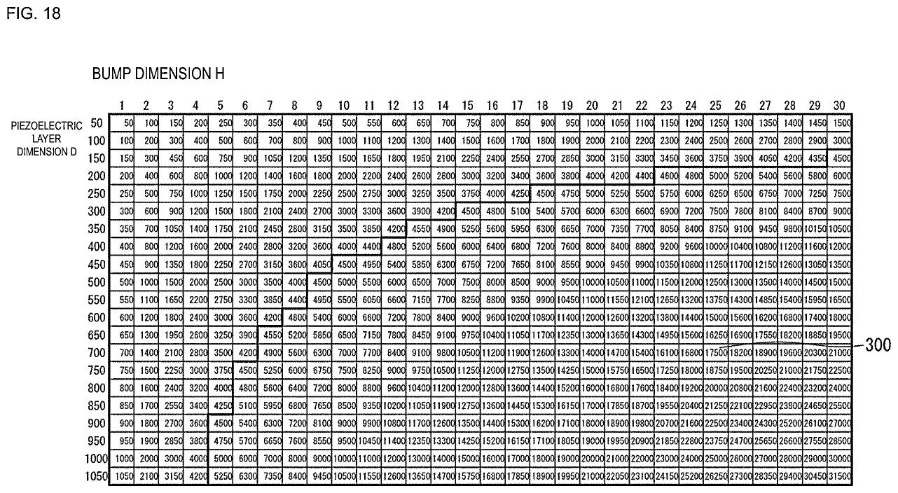

According to the results from FIGS. 15 to 17, when “the bump dimension H×the piezoelectric layer dimension W≥about 4442.9 μm·nm” is satisfied, the fixed capacitance is not less than the variable capacitance, and the variable capacitance is not dominant. FIG. 18 illustrates a region 300 satisfying “the bump dimension H×the piezoelectric layer dimension W≥about 4442.9 μm·nm”.

The bump dimension H is preferably set in a range, for example, from about 5 μm to about 100 μm. The piezoelectric layer dimension W is set in a range, for example, from about 100 nm to about 1000 nm (preferably corresponding to a wavelength of about 20 GHz to about 2.5 GHz).

As described above, the acoustic wave device 100 includes the mounting substrate 110, the acoustic wave element 1, which is positioned on the one major surface 111 of the mounting substrate 110 in its thickness direction, and the bumps 120, which are arranged between the acoustic wave element 1 and the mounting substrate 110. The acoustic wave element 1 includes the support substrate 18, which includes the air gap 9, the piezoelectric layer 2, which is stacked on the support substrate 18 and includes the overlap region 21 at least partially overlapping the air gap 9 as viewed in the stacking direction, and the functional electrode 130 disposed in the overlap region 21 of the piezoelectric layer 2. The mounting substrate 110 includes the metal portion 112. The fixed capacitance generated between the acoustic wave element 1 and the mounting substrate 110 is not less than the variable capacitance generated between the acoustic wave element 1 and the mounting substrate 110. With this configuration, the acoustic wave device 100 can be implemented so as to be less affected by variations in the bump dimension H.

The acoustic wave device 100 of the second example embodiment can also be configured as follows.

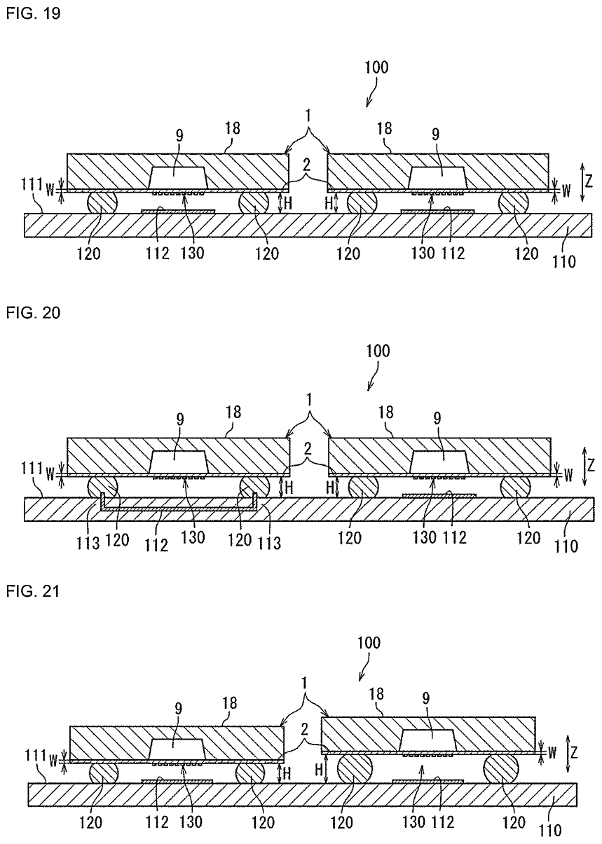

The acoustic wave device 100 is not limited to the configuration including one acoustic wave element 1 and may include a plurality of the acoustic wave elements 1. The height of the acoustic wave device 100 can therefore be determined based on the acoustic wave element 1 having the largest variations in characteristics. In this case, each acoustic wave element 1 is configured so as to satisfy Expression (1) above. FIGS. 19 to 21 illustrate examples of the acoustic wave device 100 including two acoustic wave elements 1. Each acoustic wave device 100 illustrated in FIGS. 19 to 21 includes metal portions 112 for the respective acoustic wave elements 1.

In the acoustic wave device 100 of FIG. 19, the height dimension H of each bump 120 is preferably the same as or substantially the same as that of the other bumps 120. In the acoustic wave device 100 of FIG. 20, the metal portion 112 corresponding to one of the acoustic wave elements 1 is provided for the one major surface 111 of the mounting substrate 110 while the metal portion 112 corresponding to the other acoustic wave element 1 is positioned within the mounting substrate 110. For example, the metal portion 112 positioned within the mounting substrate 110 is coupled to the corresponding bumps 120 through vias 113. Even in the acoustic wave device 100 of FIG. 20, the bump dimension H of each bump 120 is the same as that of the other bumps 120. In the acoustic wave device 100 of FIG. 21, the bump dimension H of the bumps 120 between one of the acoustic wave elements 1 and the mounting substrate 110 is different from the bump dimension H of the bumps 120 between the other acoustic wave element 1 and the mounting substrate 110. In such a manner, it is possible to set the bump dimension H of each acoustic wave element 1 to an optimal value. This can give flexibility to the layout of the acoustic wave device 100.

The acoustic wave element 1 can be manufactured by using any method, such as, for example, a method of forming the air gap 9 using a sacrificial layer or a method of etching the support substrate 18 (the support 8 and bonding layer 7, for example) from the back side.

The acoustic wave element 1 of the first example embodiment may be added with at least a portion of the configuration of the acoustic wave element 1 of the second example embodiment. The acoustic wave element 1 of the second example embodiment may be added with at least a part of the configuration of the acoustic wave element 1 of the first example embodiment.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a mounting substrate;
an acoustic wave element on one major surface of the mounting substrate in a thickness direction of the mounting substrate; and
a bump between the acoustic wave element and the mounting substrate; wherein
the acoustic wave element includes:
a support substrate including an air gap;
a piezoelectric layer stacked on the support substrate and including an overlap region at least partially overlapping the air gap as viewed in a stacking direction of the piezoelectric layer; and
a functional electrode located in the overlap region of the piezoelectric layer;
the mounting substrate includes a metal portion; and
a fixed capacitance generated between the acoustic wave element and the mounting substrate is not less than a variable capacitance generated between the acoustic wave element and the mounting substrate.

2. An acoustic wave device, comprising:
a mounting substrate;
an acoustic wave element on one major surface of the mounting substrate in a thickness direction of the mounting substrate; and
a bump between the acoustic wave element and the mounting substrate; wherein
the acoustic wave element includes:
a support substrate including an air gap;
a piezoelectric layer stacked on the support substrate and including an overlap region at least partially overlapping the air gap as viewed in a stacking direction of the piezoelectric layer; and
a functional electrode located in the overlap region of the piezoelectric layer;
the mounting substrate includes a metal portion; and
the acoustic wave device satisfies: H×W≥about 4442.9 μm·nm
where H is a bump dimension as a dimension of the bump in the stacking direction and W is a piezoelectric layer dimension as a dimension of the piezoelectric layer in the stacking direction.

3. The acoustic wave device according to claim 2, wherein the acoustic wave element includes a plurality of acoustic wave elements, and
each of the plurality of acoustic wave elements satisfies: H×W≥about 4442.9 μm·nm.

4. The acoustic wave device according to claim 3, wherein
the bump includes a plurality of bumps; and
a bump dimension of one of the plurality of bumps located between the plurality of acoustic wave elements and the mounting substrate is the same or substantially the same as a bump dimension of remaining ones of the plurality of bumps.

5. The acoustic wave device according to claim 3, wherein
the bump includes a plurality of bumps;
the plurality of acoustic wave elements include a first acoustic wave element and a second acoustic wave element; and
a bump dimension of one of the plurality of bumps between the first acoustic wave element and the mounting substrate is different from a bump dimension of another one of the plurality of bumps between the second acoustic wave element and the mounting substrate.

6. The acoustic wave device according to claim 1, wherein
the metal portion is on a major surface of the mounting substrate.

7. The acoustic wave device according to claim 1, wherein
the metal portion is within the mounting substrate.

8. The acoustic wave device according to claim 1, wherein a thickness of the piezoelectric layer is greater than or equal to about 50 nm and less than or equal to about 1000 nm.

9. The acoustic wave device according to claim 1, wherein
the piezoelectric layer is affixed to the support substrate through a support portion; and
an insulating layer is interposed between the support portion and the piezoelectric layer.

10. The acoustic wave device according to claim 9, wherein
the support portion is made of Si with a resistivity of about 4 kΩ or more.

11. The acoustic wave device according to claim 1, wherein
the functional electrode in an interdigital transducer electrode including a first busbar, a second busbar, first electrode fingers connected to the first busbar, and second electrode fingers connected to the second busbar.

12. The acoustic wave device according to claim 2, wherein
H is between 5 and 100, inclusive; and
W is between 100 and 1000, inclusive.
